(19) United States
(12) Patent Application Publication
(10) Pub. No.: US 2023/0306245 A1
(43) Pub. Date: Sep. 28, 2023

(54) PROGRAMMING CIRCUIT, INTEGRATED CIRCUIT, AND METHOD

(71) Applicant: TAIWAN SEMICONDUCTOR MANUFACTURING COMPANY, LTD., Hsinchu (TW)

(72) Inventors: Jen-Chieh LIU, Hsinchu (TW); Win-San KHWA, Hsinchu (TW); Jui-Jen WU, Hsinchu (TW); Meng-Fan CHANG, Hsinchu (TW)

(21) Appl. No.: 17/703,889

(22) Filed: Mar. 24, 2022

(51) Int. Cl. G06N 3/063; G11C 13/00; G11C 11/54

(52) U.S. Cl. CPC G06N 3/063; G11C 13/0004; G11C 13/0069; G11C 13/0061; G11C 13/0097; G11C 13/003; G11C 11/54; G11C 2213/79

(57) ABSTRACT

A programming circuit includes a time difference converter circuit and a pulse generator circuit. The converter circuit is configured to receive a first pulse from a first neuron device and a second pulse from a second neuron device, and to output a time difference signal corresponding to a time difference between the first pulse and the second pulse. The pulse generator circuit includes an input coupled to the output of the time difference converter circuit to receive the time difference signal, and an output at which the pulse generator circuit is configured to output a program voltage corresponding to the time difference signal. The output of the pulse generator circuit is configured to be coupled to a synapse device coupled between the first neuron device and the second neuron device to program a weight value in the synapse device with the program voltage.

### BACKGROUND

Recent developments in the field of artificial intelligence have resulted in various products and/or applications, including, but not limited to, speech recognition, image processing, machine learning, natural language processing, or the like. Such products and/or applications often use neural networks to process large amounts of data for learning, training, cognitive computing, or the like.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic diagram of a neural network, and FIG. 1B is a schematic diagram of a portion of the neural network, in accordance with some embodiments.

FIGS. 2A and 2B are schematic diagrams of various integrated circuits, in accordance with some embodiments.

FIG. 3 is a schematic diagram of a programing circuit, in accordance with some embodiments.

FIG. 4 is a schematic diagram of a programing circuit, in accordance with some embodiments.

FIG. 5A is a schematic diagram of a programing circuit, and FIG. 5B is a timing diagram showing example program voltages generated by the programing circuit, in accordance with some embodiments.

FIG. 6A is a schematic diagram of a programing circuit, and FIGS. 6B-6C are timing diagrams showing example program voltages generated by the programing circuit, in accordance with some embodiments.

FIG. 7 is a flowchart of a method in accordance with some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

A neural network is implemented by one or more matrices or arrays of memory cells. Each memory cell array stores weight data which are trained or learned in a training or learning process. In a learning process in accordance with spike-timing dependent plasticity (STDP), a pulse generated at one side, e.g., an input side, of the memory cell array, and another pulse generated at another side, e.g., an output side, of the memory cell array are used to adjust weight data stored in a corresponding memory cell of the memory cell array. In some embodiments, both pulses are supplied to a programming circuit at one side, which is either the input side or the output side, of the memory cell array. The programming circuit is configured to detect a time difference between the two pulses, generate a program voltage corresponding to the detected time difference, and supply the program voltage from the one side to the memory cell array to adjust the weight data stored in the corresponding memory cell. In at least one embodiment, by supplying the program voltage to the memory cell from one side of the memory cell array, it is possible to reduce one or more of circuit complexity, circuit area, power consumption, efficiency, input distortion, scalability limitation, or the like. These are improvements over other approaches in which pulses for programming a memory cell are supplied to the memory cell array from both the input side and the output side. Further features and/or advantages in accordance with various embodiments are described herein.

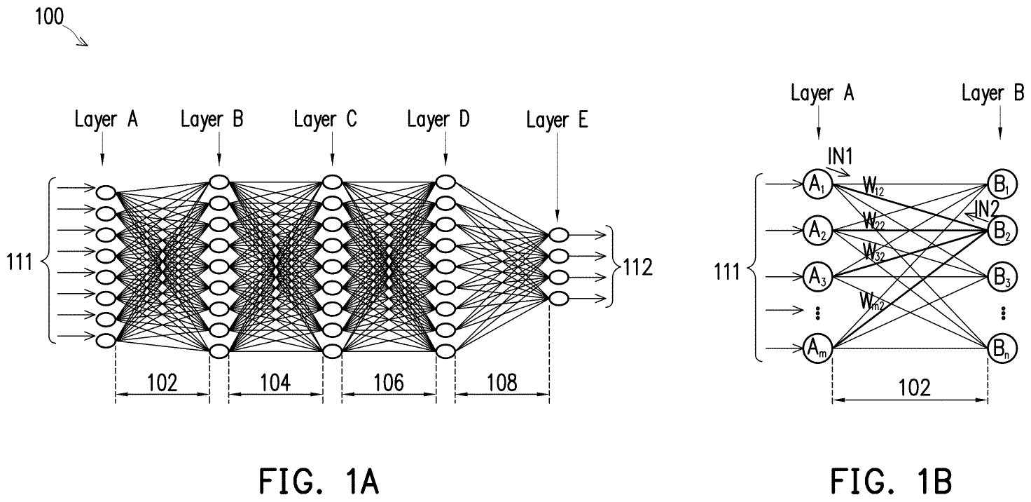

FIG. 1A is a schematic diagram of a neural network 100, in accordance with some embodiments.

The neural network 100 comprises a plurality of layers A-E each comprising a plurality of nodes (also referred to as “neurons” or “neuron devices”). The nodes in successive layers of the neural network 100 are connected with each other by a matrix or array of connections. For example, the nodes in layers A and B are connected with each other by connections in a matrix 102, the nodes in layers B and C are connected with each other by connections in a matrix 104, the nodes in layers C and D are connected with each other by connections in a matrix 106, and the nodes in layers D and E are connected with each other by connections in a matrix 108. Layer A is a start layer configured to receive input data 111. The input data 111 propagate through the neural network 100, from one layer to the next layer via the corresponding matrix of connections between the layers. As the data propagate through the neural network 100, the data undergo one or more computations, and are output as output data 112 from layer E which is an end layer of the neural network 100. Layers B, C, D between start layer A and end layer E are sometimes referred to as hidden or intermediate layers. The number of layers, number of matrices of connections, and number of nodes in each layer in FIG. 1A are examples. Other configurations are within the scopes of various embodiments. For example, in at least one embodiment, the neural network 100 includes no hidden layer, and has a start layer connected by one matrix of connections to an end layer. In one or more embodiments, the neural network 100 has one, two, or more than three hidden layers.

FIG. 1B is a schematic view of the matrix 102 and associated layers A and B of the neural network 100. Other layers C, D, E and matrices 104, 106, 108 are configured similarly to layers A, B and the matrix 102, and are not described in detail herein.

As illustrated in FIG. 1B, layer A comprises m nodes identified as nodes A₁, A₂, A₃ to Aₘ, and layer B comprises n nodes identified as nodes B₁, B₂, B₃ to Bₙ, where m and n are positive integers. In some embodiments, m is equal to n. In one or more embodiments, m is different from n. In at least one embodiment, at least one of m or n is equal to 1, i.e., the corresponding layer has one node (one neuron). Each node of layer A is connected to one or more nodes of layer B, and vice versa. In the example configuration in FIG. 1B, each node of layer A is connected to all nodes of layer B, and vice versa. Other configurations are within the scopes of various embodiments. In the matrix 102, a connection between a node in layer A and another node in layer B has a corresponding weight (also referred to as “weight value”). For example, a connection between node A₁ and node B₂ has a weight W₁₂, a connection between node A₂ and node B₂ has a weight W₂₂, a connection between node A₃ and node B₂ has a weight W₃₂, and a connection between node Aₘ and node B₂ has a weight Wₘ₂. In the description herein, a connection is referred to by the corresponding weight, and a value of a node is denoted by the name of the node. For example, the connection with the weight W₁₂ is referred to as connection W₁₂, and node A₁ has value A₁, or the like.

In at least one embodiment, value B₂ at node B₂ is calculated by the following activation function (1):

B₂=A₁×W₁₂+A₂×W₂₂+A₃×W₃₂ . . . +Aₘ×Wₘ₂ (1)

A generalized form of activation function (1) is given as the following activation function (2):

Bⱼ=Σᵢ₌₁^{m}Aᵢ×Wᵢⱼ (2)

where i=1, 2, . . . m, j=1, 2, . . . n, and Wᵢⱼ is the weight of the connection connecting node Aᵢ and node Bⱼ.

The input data 111 comprise values A₁, A₂, A₃, . . . Aₘ applied to corresponding nodes A₁, A₂, A₃ to Aₘ. Values B₁, B₂, B₃ to Bₙ are calculated from input values A₁, A₂, A₃, . . . Aₘ and the corresponding weights Wᵢⱼ based on activation function (2). Calculated values B₁, B₂, B₃ to Bₙ are then used, together with corresponding weights of connections in the matrix 104, to calculate values at the nodes of layer C by using one or more corresponding activation functions. Values at the nodes in subsequent layers D and E are calculated in a similar manner, resulting in the output data 112 being output from end layer E of the neural network 100. The described activation functions (1) and (2) are examples. Other activation functions for calculating values at nodes in the neural network 100 are within the scopes of various embodiments.

Each of the weights Wᵢⱼ is stored in a memory cell (also referred to herein as “synapse device”) coupled between corresponding nodes A₁ and B₃. In other words, the memory cell corresponds to the connection W₁₂ between nodes A, and B₃ stores the corresponding weight W₁₂. The weights Wᵢⱼ are learned or trained in a learning or training process. An example learning process includes a spike-timing dependent plasticity (STDP) operation described herein with respect to the memory cell (or synapse device) coupled between nodes A₁ and B₂ and storing the weight W₁₂. Node A₁ coupled to an input side of the memory cell is referred to herein as an input neuron device or pre-synaptic neuron device (with respect to the memory cell). Node B₂ coupled to an output side of the memory cell is referred to herein as an output neuron device or post-synaptic neuron device (with respect to the memory cell). In some embodiments, the neuron devices in the CPE system 100 have a leaky integrate and fire (LIF) configuration, a Stochastically firing LIF (S-LIF) configuration, or the like. Other neuron device configurations are within the scopes of various embodiments. For simplicity, the memory cell or synapse device corresponding to the connection between node A₁ and node B₂ is referred to herein by the corresponding weight W₁₂.

In an example embodiment, each neuron device comprises an integrating circuit and a comparator circuit. The integrating circuit is configured to integrate inputs from neuron devices of the immediately upstream layer propagating through the corresponding weighted connections, as described herein with respect to function (2). When an integrated value, voltage or current generated by the integrating circuit exceeds a threshold of the corresponding comparator circuit, the comparator circuit outputs a pulse or spike indicating that the neuron device fires (or spikes). The pulse output by the spiking neuron device is sent both upstream and downstream to the neuron devices in the immediately adjacent layers that are connected to the spiking neuron device. For example, when the neuron device A₁ spikes, the neuron device A₁ is configured to send a pulse IN1 to the neuron devices B₁, B₂, B₃ to Bₙ in the immediately downstream layer B. For simplicity, the pulse IN1 is illustrated for the connection Wiz and is omitted from the other connections. When the neuron device B₂ spikes, the neuron device B₂ is configured to send a pulse IN2 both upstream to the neuron devices in layer A and downstream to neuron devices in layer C (not shown in FIG. 1B). For simplicity, the pulse IN2 is illustrated for the connection W₁₂ and is omitted from the other connections. Each of the pulse IN1 and pulse IN2 alone is insufficient to program the memory cell or synapse device W₁₂, i.e., insufficient to change the stored weight W₁₂. In accordance with an STDP rule, the weight (corresponding to conductance) of the synapse device W₁₂ is to be changed based on a relative timing between the pulse IN1 and pulse IN2. In some embodiments, the conductance of the synapse device W₁₂ is increased when the post-synaptic neuron device (e.g., node B₂) fires after the pre-synaptic neuron device (node A₁), i.e., when the pulse IN2 is generated after the pulse IN1. This corresponds to a long term potentiation (LTP) in the STDP rule. The conductance of the synapse device W₁₂ is decreased when the post-synaptic neuron device (e.g., node B₂) fires before the pre-synaptic neuron device (node A₁), i.e., when the pulse IN2 is generated before the pulse IN1. This corresponds to a long term depression (LTD) in the STDP rule. Other STDP configurations are within the scopes of various embodiments. The weights Wᵢⱼ are adjusted, i.e., increased or decreased, multiple times during the learning process. Once trained, the neural network 100 is usable to process actual input data, e.g., for image processing, faces recognition, natural language processing, or the like. The described training process and applications of the neural network 100 are examples. Other applications and/or training processes are within the scopes of various embodiments.

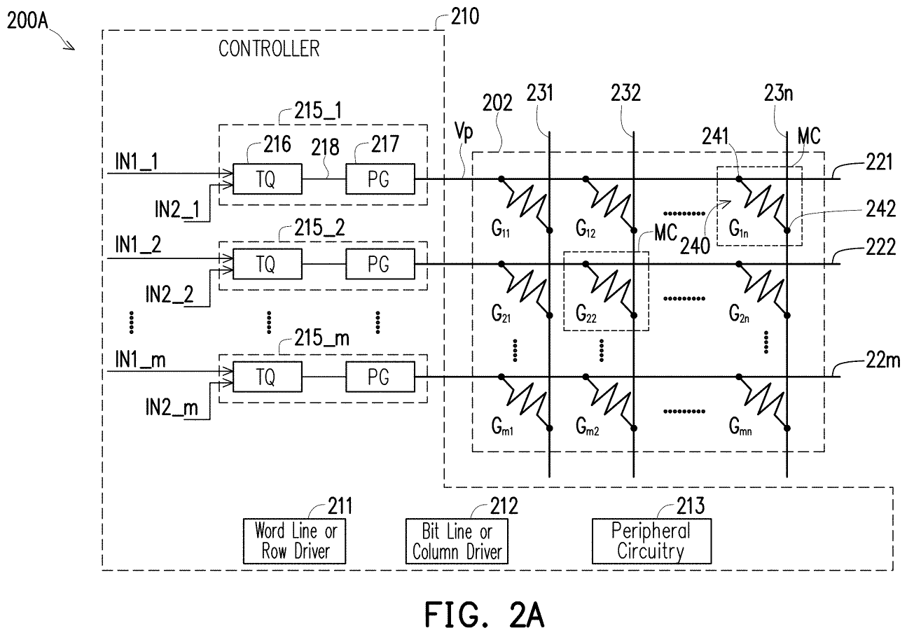

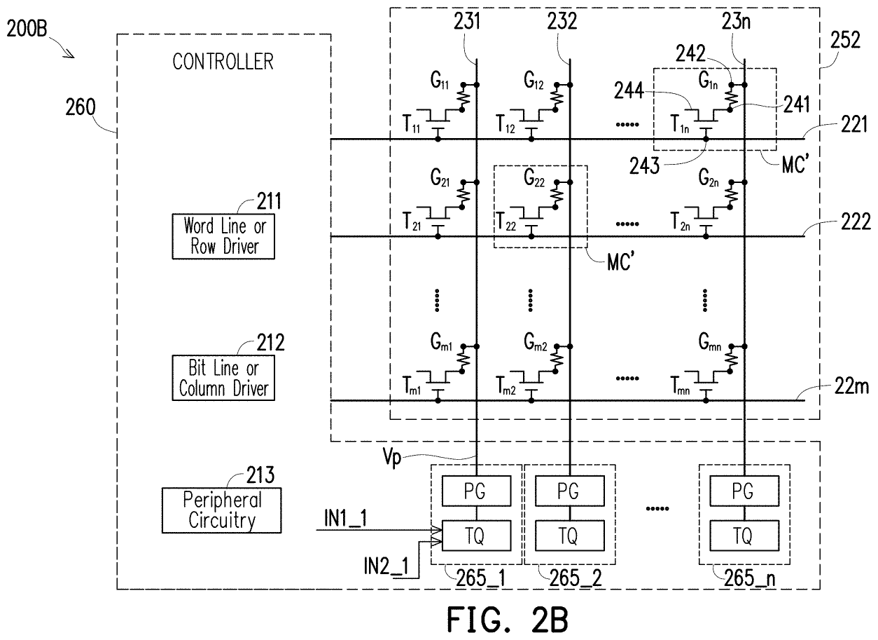

FIG. 2A is a schematic diagram of an integrated circuit (IC) 200A, in accordance with some embodiments. In at least one embodiment, the IC 200A is configured as a neural network, or as a portion of a neural network as described with respect to FIGS. 1A-1B. The IC 200A comprises a memory cell array (or memory array) 202, and a controller 210.

In the example configuration in FIG. 2A, the memory array 202 corresponds to the matrix 102 described with respect to FIG. 1B, and is an m×n array, where m and n are positive integers, with m first conductive lines 221, 222, . . . 22m, n second conductive lines 231, 232, . . . 23n, and a plurality of memory cells MC each coupled to a corresponding first conductive line among the m first conductive lines 221, 222, . . . 22m and a corresponding second conductive line among the n second conductive lines 231, 232, . . . 23n. In some embodiments, the first conductive lines 221, 222, . . . 22m are input conductive lines correspondingly coupled to input neuron devices, and the n second conductive lines 231, 232, . . . 23n are output conductive lines correspondingly coupled to output neuron devices. The input neuron devices correspond to nodes A₁, A₂, A₃ to Aₘ described with respect to FIG. 1B, and are omitted from FIG. 2A for simplicity. The output neuron devices correspond to nodes B₁, B₂, B₃ to Bₙ described with respect to FIG. 1B, and are omitted from FIG. 2A for simplicity. In at least one embodiment, the roles of the first conductive lines 221, 222, . . . 22m and the n second conductive lines 231, 232, . . . 23n are reversed, i.e., the first conductive lines 221, 222, . . . 22m are output conductive lines correspondingly coupled to output neuron devices, and the n second conductive lines 231, 232, . . . 23n are input conductive lines correspondingly coupled to input neuron devices.

Each memory cell MC of the memory array 202 comprises a controllably variable resistor having a conductance (or resistance) adjustable or programmable, e.g., under control of the controller 210 and/or in a learning process as described herein. Example configurations of controllably variable resistors include, but are not limited to, memristor, resistive random-access memory (RRAM), magnetoresistive RAM (MRAM), phase change RAM (PCRAM or PCM), or the like. For simplicity, several embodiments including PCM are specifically described herein. The configurations and/or operations described with respect to PCM are applicable to other types of controllably variable resistors.

In the example configuration in FIG. 2A, each controllably variable resistor of a corresponding memory cell MC is electrically coupled between a corresponding first conductive line 22i (where i is 1, 2, . . . m) and a corresponding second conductive line 23j (where j is 1, 2, . . . n), and has a corresponding conductance Gᵢⱼ corresponding to the datum or weight stored in the memory cell MC. For example, a controllably variable resistor 240 has a first terminal 241 coupled to the corresponding first conductive line 221 and a second terminal 242 coupled to the corresponding second conductive line 23n, and the controllably variable resistor 240 has a corresponding conductance G₁ₙ. For simplicity, a memory cell MC is referred to herein by the conductance of the corresponding controllably variable resistor. For example, a memory cell MC having the corresponding controllably variable resistor electrically coupled between the first conductive line 221 and the second conductive line 231 is sometimes referred to by the corresponding conductance G₁₁. For another example, a memory cell MC having the corresponding controllably variable resistor electrically coupled between the first conductive line 22m and the second conductive line 23n is sometimes referred to by the corresponding conductance Gₘₙ. In some embodiments, the conductance Gᵢⱼ corresponds to the weight Wu described with respect to FIG. 1B. For example, the conductance G₁₂ of the controllably variable resistor electrically coupled between the first conductive line 221 and the second conductive line 232 corresponds to weight Wiz of the connection between node A₁ and node B₂ described with respect to FIG. 1B.

The controller 210 is electrically coupled to the memory cells MC in the memory array 202 through the first conductive lines 221, 222, . . . 22m and the second conductive lines 231, 232, . . . 23n, and configured to control operations of the memory cells MC including, but not limited to, a read operation, a write operation, or the like. Write operations include, but are not limited to, programming operation, set operation, reset operations, or the like. In the example configuration in FIG. 2, the controller 210 comprises at least one row driver 211, at least one column driver 212, peripheral circuitry 213, and a plurality of programming circuits 215_1, 215_2 to 215_m. The programming circuits 215_1, 215_2 to 215_m are collectively referred to herein as programming circuits 215. In at least one embodiment, the controller 210 further comprises one or more clock generators for providing clock signals for various components of the IC 200A, one or more input/output (I/O) circuits for data exchange with external devices, and/or one or more controllers for controlling various operations in the IC 200A.

The row driver 211 is coupled to and configured to drive the first conductive lines 221, 222, . . . 22m which are arranged along the rows of the memory array 202. The column driver 212 is coupled to and configured to drive the second conductive lines 231, 232, . . . 23n which are arranged along the columns of the memory array 202. In some embodiments, the first conductive lines 221, 222, . . . 22m comprise a plurality of word lines (also referred to as “address lines”), the second conductive lines 231, 232, . . . 23n comprise a plurality of bit lines (also referred to as “data lines”), the row driver 211 comprises at least one word line driver, and the column driver 212 comprises at least one bit line driver. The described configuration is an example. In at least one embodiment, the first conductive lines 221, 222, . . . 22m comprise bit lines, the second conductive lines 231, 232, . . . 23n comprise word lines, the row driver 211 comprises at least one bit line driver, and the column driver 212 comprises at least one word line driver. In some embodiments, word lines are configured for transmitting addresses of the memory cells MC to be read from, or for transmitting addresses of the memory cells MC to be written to, or the like. In at least one embodiment, a set of word lines is configured to perform as both read word lines and write word lines. Examples of bit lines include read bit lines for transmitting data read from the memory cells MC indicated by corresponding word lines, write bit lines for transmitting data to be written to the memory cells MC indicated by corresponding word lines, or the like. In at least one embodiment, a set of bit lines is configured to perform as both read bit lines and write bit lines. Various numbers of word lines and/or bit lines in the memory array 202 are within the scope of various embodiments. The row driver or word line driver 211 is coupled to the memory array 202 via the word lines, and are configured to decode a row address of a memory cell MC selected to be accessed in a read operation or a write operation. The word line driver 211 is configured to supply a voltage to the selected word line corresponding to the decoded row address, and a different voltage to the other, unselected word lines. The column driver or bit line driver 212 is coupled to the memory array 202 via the bit lines. The bit line driver 212 is configured to decode a column address of the memory cell MC selected to be accessed in a read operation or a write operation. The bit line driver 212 is configured to supply a voltage to the selected bit line corresponding to the decoded column address, and a different voltage to the other, unselected bit lines.

The peripheral circuitry 213 is coupled to the memory array 202 via the bit lines and/or the word lines. In some embodiments, the peripheral circuitry 213 comprises one or more of output neuron devices, input neuron devices, sense amplifiers (SA), or the like.

The programming circuits 215 are correspondingly coupled to the first conductive lines 221, 222, . . . 22m. Each of the programming circuits 215 is configured to detect a time difference between a first pulse and a second pulse, generate a program voltage corresponding to the detected time difference, and output the generated program voltage to the corresponding first conductive line to program a corresponding memory cell in the array of memory cells with the program voltage. For example, the programming circuit 215_1 is coupled to the first conductive line 221, the programming circuit 215_2 is coupled to the first conductive line 222, or the like. The programming circuit 215_1 is configured to detect a time difference between a first pulse IN1_1 and a second pulse IN2_1, and generate a program voltage Vp corresponding to the detected time difference, and output the generated program voltage Vp to the corresponding first conductive line 221 to program a corresponding memory cell among the memory cells coupled to the first conductive line 221 with the program voltage Vp.

In some embodiments, the first pulse IN1_1 is generated by a spiking pre-synaptic neuron device, the second pulse IN2_1 is generated by a spiking post-synaptic neuron device, and the corresponding program voltage Vp is to program the corresponding memory cell MC (or synapse device) coupled between the spiking pre-synaptic neuron device and the spiking post-synaptic neuron device. For example, when the first pulse IN1_1 is generated by a pre-synaptic neuron device corresponding to node A₁, and the second pulse IN2_1 is generated by a post-synaptic neuron device corresponding to node B₂, the program voltage Vp is generated by the programming circuit 215_1 and output to the first conductive line 221 to program the corresponding memory cell G₁₂. In some embodiments, during the program operation of the memory cell G₁₂, the corresponding second conductive line 232 coupled to the memory cell G₁₂ is grounded so that the program voltage Vp is applied across the corresponding controllably variable resistor, whereas other second conductive lines 231 to 23n are left floating to prevent the program voltage Vp from affecting the weight data stored in the other memory cells MC coupled to the same first conductive line 221. At least one of the duration, waveform inclination, or maximum voltage value of the program voltage Vp is variable dependent on the time difference between the first pulse IN1_1 and the second pulse IN2_1 as described herein.

In the example configuration in FIG. 2A, the programming circuit 215_1 comprises a time difference converter circuit 216 (designated in FIG. 2A as “TQ”) and a pulse generator circuit 217 (designated in FIG. 2A as “PG”). The time difference converter circuit 216 is configured to detect the time difference and output a time difference signal 218 corresponding to the detected time difference to the pulse generator circuit 217. The pulse generator circuit 217 is configured to generate the program voltage Vp corresponding to the time difference signal 218. Further details of the time difference converter circuit and pulse generator circuit in accordance with some embodiments are described herein.

In some embodiments, the time difference converter circuit 216 is coupled to one or more write drivers in the controller 210 to receive the first pulse IN1_1 and second pulse IN2_1. In at least one embodiment, each of the first pulse IN1_1 and the second pulse IN2_1 alone and/or as received from the corresponding write driver(s) is insufficient to program the corresponding memory cell. The pulse generator circuit 217 is configured to, based on the time difference between the first pulse IN1_1 and second pulse IN2_1, generate the program voltage Vp with sufficient voltage and/or power to program the corresponding memory cell. In at least one embodiment, the pulse generator circuit 217 has a capability and/or configuration similar to that of a word line driver to be able to drive the first conductive line 221 and to program one or more memory cells coupled thereto. The other programming circuits 215_2 to 215_m are configured and/or operate in a similar manner to the programming circuit 215_1.

The configuration described with respect to FIG. 2A in which the programming circuits 215 are coupled to the first conductive lines 221, 222, . . . 22m, or to the input side of the memory array 202 is an example. In at least one embodiment, the programming circuits 215 are instead coupled to the second conductive lines 231, 232, . . . 23n, or to the output side of the memory array 202. In either configuration, the programming circuits 215 are provided at one side of the memory array 202, e.g., either on the input side coupled to input neuron devices, or on the output side coupled to output neuron devices.

In at least one embodiment, by arranging the programming circuits 215 at one side (i.e., the input side or output side), but not at the other (output or input) side, of the memory array 202, it is possible to reduce at least one of circuit complexity, circuit area, or power consumption. A reason is that the pulse generator circuit 217, in some embodiments, comprises a large circuit to enable the pulse generator circuit 217 to drive the corresponding conductive line and to program one or more memory cells coupled thereto. By arranging programming circuits 215 at one side of the memory array 202, it is possible, in one or more embodiments, to provide large pulse generator circuits at that one side of the memory array 202 and omit such large pulse generator circuits from the other side of the memory array 202. As a result, one or more of circuit complexity, circuit area, power consumption is/are advantageously reduced in one or more embodiments.

The described features and advantages in accordance with some embodiments are improvements over other approaches in which pulses for programing a memory cell in accordance with the STDP rule are supplied to the memory cell from both the input side and the output side of the memory cell array. Each of such pulses requires a corresponding pulse generator to output the pulse with a sufficient voltage and/or power to the memory cell to be programed. As a result, pulse generators, which are large circuits, are required on both input and output sides of the memory cell array which, in turn, causes increases in circuit complexity, circuit area and power consumption.

In some situations, the other approaches also suffer from input distortion due to a difference in the arrival times of the two pulses from opposite sides of a targeted memory cell to be programed in accordance with the STDP rule. The arrival times of the two pulses to the targeted memory cell require precise control, in order to program the memory cell by the voltage difference of the two pulses one of which is a negative voltage pulse while the other is a positive voltage pulse. There is a further limitation to scalability in other approaches due to increasing parasitic resistance-capacitance which occurs when large memory cell arrays are implemented at advanced technology nodes.

One or more of the above issues of the other approaches are avoidable in accordance with some embodiments. For example, in at least one embodiment, precise and/or robust STDP performance is achievable and/or negative effects of parasitic resistance-capacitance are reduced, because the targeted memory cell is programed by the program voltage Vp supplied from one side and therefore, arrival time difference is no longer an issue. In some embodiments, the circuit area for pulse generators provided at one side of the memory array is reduced by about 50%, compared to the other approaches with pulse generators provided at both sides of the memory array, which, in turn, improves the area efficiency of the IC 200A.

In some embodiments, the pulse generator circuits are similar to those usable in multi-level memory devices, and require minimal or no redesigning efforts. The time difference converter circuits are configurable from standard logic circuits which require minimal designing efforts. As a result, programming circuits and/or ICs in accordance with one or more embodiments are quickly adaptable to current circuit designs.

In some embodiments, because the pulse generator circuits are similar to those usable in multi-level memory devices, the waveforms of program voltages generated by the pulse generator circuits include one or more square or rectangle pulses similar to those used in memory applications. In at least one embodiment, this is an advantage over the other approaches where it is required to design programming voltages to match the characteristics of the memory device to be programed. In one or more embodiments, it is easier to accelerate the operation due to the simpler waveform configurations/designs.

In at least one embodiment, it is possible to achieve a higher throughput, by performing a pipeline operation in the IC 200A. For example, in one or more embodiments, while the pulse generator circuit 217 is programing a selected memory cell according to the time difference data of a previous programming operation or cycle, the time difference converter circuit 216 is configured to receive pulses from spiking neuron devices for a next programming operation or cycle. This pipeline operation makes it possible to potentially achieve higher throughput in at least one embodiment.

In some embodiments, a shorter array operation time is achievable, because the input timing is decoupled from the actual programming time. Specifically, in the other approaches, when a selected memory cell is being programmed according to two inputted pulses transmitted from both sides of the memory cell, e.g., through the corresponding bit line and the corresponding word line, the selected memory cell and the corresponding bit line and word line are all occupied while the inputted pulses are being delivered. In contrast, in some embodiments, the time difference converter circuit 216, which is configured to handle the inputted pulses (e.g., the first pulse IN1_1 and the second pulse IN2_1), is external to memory array 202. Therefore, while the time difference converter circuit 216 is detecting the time difference of the two inputted pulses and generating the corresponding time difference signal 218 for the pulse generator circuit 217, the selected memory cell and the corresponding bit line and word line are available for another operation, such as a read operation.

In some embodiments, it is possible to further reduce the duration of the program operation by increasing the amplitude of the program voltage Vp, so as to accelerate the programming of the targeted memory cell with the program voltage Vp.

Some embodiments provide a single-sided STDP implementation for training memory cells in a memory cell array for a neural network, by generating program voltages in circuitry peripheral to the memory cell array. In at least one embodiment where the memory cells are PCM cells, the program voltages for setting the PCM cells are based on the quenching-dependent behavior of PCM. One or more embodiments comprise replacing one set of large, analog pulse generators at either the input side or the output of the memory cell array with a set of time difference converter circuits at the other side. The time difference converter circuits entirely include digital circuits, or include a mixed configuration of digital and analog circuits. In any event, the size or area of the time difference converter circuits is much smaller than that of the pulse generators being replaced, resulting in one or more advantages discussed herein with respect to some embodiments.

FIG. 2B is a schematic diagram of an IC 200B, in accordance with some embodiments. In at least one embodiment, the IC 200B is configured as a neural network, or as a portion of a neural network as described with respect to FIGS. 1A-1B. Components of the IC 200B having corresponding components in the IC 200A are designated by the same reference numerals. The IC 200B comprises a memory array 252 corresponding to the memory array 202, and a controller 260 corresponding to the controller 210.

A difference between the memory array 202 and the memory array 252 resides in the configuration of the corresponding memory cells. Compared to the memory cells MC in the memory array 202, each of memory cells MC′ in the memory array 252 comprises an access transistor Tᵢⱼ in addition to the controllably variable resistor Gᵢⱼ where i is 1, 2, . . . m and j is 1, 2, . . . n. For example, the memory cell MC′ coupled to the first conductive line 221 and the second conductive line 23n comprises a controllably variable resistor Gin and an access transistor Tin. The controllably variable resistor Gin has a first terminal 241, and a second terminal 242 coupled to the corresponding second conductive line 23n. The access transistor Tin has a gate terminal 243 coupled to the corresponding first conductive line 221, and a drain or source terminal (not numbered) coupled to the first terminal 241 of the controllably variable resistor Gin. Another drain or source terminal 244 of the access transistor T₁ₙ is controlled to be floating, grounded, or supplied with a reference voltage. The described configuration of the memory cells MC′ is also referred to as 1T1R (one transistor, one resistor). Other configurations, e.g., 2T1R (two transistors, one resistor), or the like, are within the scopes of various embodiments.

Each of the first conductive lines 221, 222, . . . 22m is configured as a word line for delivering an appropriate voltage to turn ON the access transistor of a selected or targeted memory cell. When the access transistor is turned ON, a read operation or a program operation of the corresponding controllably variable resistor is enabled. When the access transistor is turned OFF, access to the corresponding controllably variable resistor, i.e., for a read operation or a program operation, is disabled. Each of the second conductive lines 231, 232, . . . 23n is configured as a bit line or source line. The second conductive lines 231, 232, . . . 23n are correspondingly coupled to a plurality of programming circuits 265_1, 265_2 to 265_n, which are collectively referred to as programming circuits 265 and are configured similarly to the programming circuits 215 in the IC 200A. Like the IC 200A, the programming circuits 265 in the IC 200B are provided at one side, e.g., either the input side or the output side, of the memory array 252. The programing of each controllably variable resistor Gᵢⱼ in the memory array 252 is performed by a program voltage Vp generated and applied, from the one side of the memory array 252, in a manner similar to the IC 200A. A difference from the IC 200A is that the program voltage Vp is applied to the corresponding second conductive line 23j, which is a bit line or source line, when the corresponding access transistor Tᵢⱼ is turned ON by an appropriate voltage on the corresponding first conductive line 22i, which is a word line.

The configuration described with respect to FIG. 2B is an example. Other configurations are within the scopes of various embodiments. For example, in some embodiments, the gate terminal of each of the access transistor Tᵢⱼ is coupled to the corresponding second conductive line 23j, and one of the terminal of the corresponding controllably variable resistor Gᵢⱼ is coupled to the corresponding first conductive line 22i. In at least one embodiment, one or more advantages described herein with respect to the IC 200A are achievable by the IC 200B.

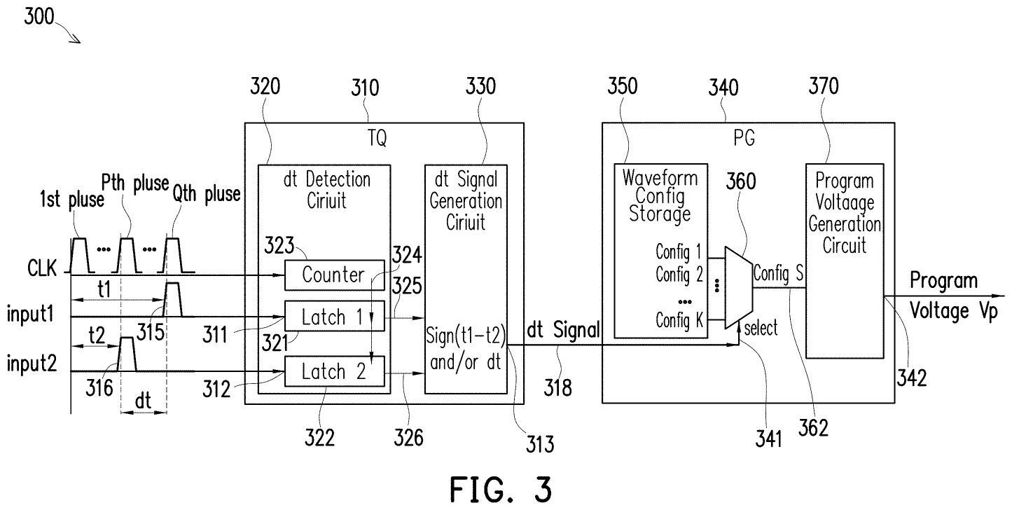

FIG. 3 is a schematic diagram of a programing circuit 300, in accordance with some embodiments. In at least one embodiment, the programing circuit 300 corresponds to one or more of the programming circuits 215, 265 described with respect to FIGS. 2A-2B.

The programing circuit 300 comprises a time difference converter circuit 310, and a pulse generator circuit 340. In at least one embodiment, the time difference converter circuit 310 corresponds to the time difference converter circuit 216, and/or the pulse generator circuit 340 corresponds to the pulse generator circuit 217.

The time difference converter circuit 310 comprises a first input 311 configured to receive a first pulse input1 from a first neuron device in a neural network, a second input 312 configured to receive a second pulse input2 from a second neuron device in the neural network, and an output 313. The neural network further comprises a synapse device coupled between the first neuron device and the second neuron device. In at least one embodiment, the neural network, first neuron device, second neuron device, and synapse device, correspond to the neural network 100, any pre-synaptic neuron device (e.g., node A₁) in the neural network 100, any post-synaptic neuron device (e.g., node B₂) in the neural network 100, and the corresponding synapse device (e.g., the memory cell corresponding to the connection W₁₂) between the pre-synaptic neuron device and post-synaptic neuron device. In one or more embodiments, the pair of first pulse input1 and second pulse input2 corresponds to a pair of pulses generated by the spiking pre-synaptic neuron device and post-synaptic neuron device, such as the pair of first pulse IN1 and second pulse IN2, or the pair of first pulse IN1_1 and second pulse IN2_1. The time difference converter circuit 310 is configured to output, at the output 313, a time difference signal 318 corresponding to a time difference dt between the first pulse input1 and the second pulse input2.

In the example configuration in FIG. 3, the time difference converter circuit 310 comprises a time difference detection circuit 320 and a time difference signal generation circuit 330 (“time difference” is abbreviated as “dt” in the drawings). The time difference detection circuit 320 is configured to detect the time difference dt between the first pulse input1 and the second pulse input2. The time difference signal generation circuit 330 is coupled to the time difference detection circuit 320 and configured to generate the time difference signal 318 based on the detected time difference dt.

The time difference detection circuit 320, in the example configuration in FIG. 3, comprises a first latch 321, a second latch 322, and a counter 323. The counter 323 is configured to receive a clock signal CLK, and start counting clock pulses (or clock cycles) in the clock signal CLK in response to a start signal (not shown) corresponding to a start of a program operation. The counter 323 is configured to generate a count value signal 324 based on the clock signal CLK, and output the count value signal 324 to the first latch 321 and the second latch 322. The counted number of clock pulses (or clock cycles) in the clock signal CLK is updated in the count value signal 324 as the counter 323 continues the counting operation.

The first latch 321 comprises the first input 311 of the time difference converter circuit 310, is configured to receive the first pulse input1 at the first input 311, and is configured to latch the counted number of clock pulses in the count value signal 324 when the first pulse input1 arrives. In the example in FIG. 3, when a rising edge 315 of the first pulse input1 is detected, the counter 323 has counted a Q^{th} pulse, and the counted number of clock pulses in the count value signal 324 is Q. The value Q is latched by the first latch 321 and is output as a first signal 325 from an output of the first latch 321. The value Q corresponds to an arrival time t1 between the first pulse counted by the counter 323 when the counting operation started, and the arrival (or detection) of the first pulse input1.

The second latch 322 comprises the second input 312 of the time difference converter circuit 310, is configured to receive the second pulse input2 at the second input 312, and is configured to latch the counted number of clock pulses in the count value signal 324 when the second pulse input2 arrives. In the example in FIG. 3, when a rising edge 316 of the second pulse input2 is detected, the counter 323 has counted a P^{th} pulse, and the counted number of clock pulses in the count value signal 324 is P. The value P is latched by the second latch 322 and is output as a second signal 326 from an output of the second latch 322. The value P corresponds to an arrival time t2 between the first pulse counted by the counter 323 when the counting operation started, and the arrival (or detection) of the second pulse input2. The time difference dt between the first pulse input1 and the pulse input2 corresponds to a difference between the latched values Q and P, i.e., the time difference dt corresponds to (Q−P).

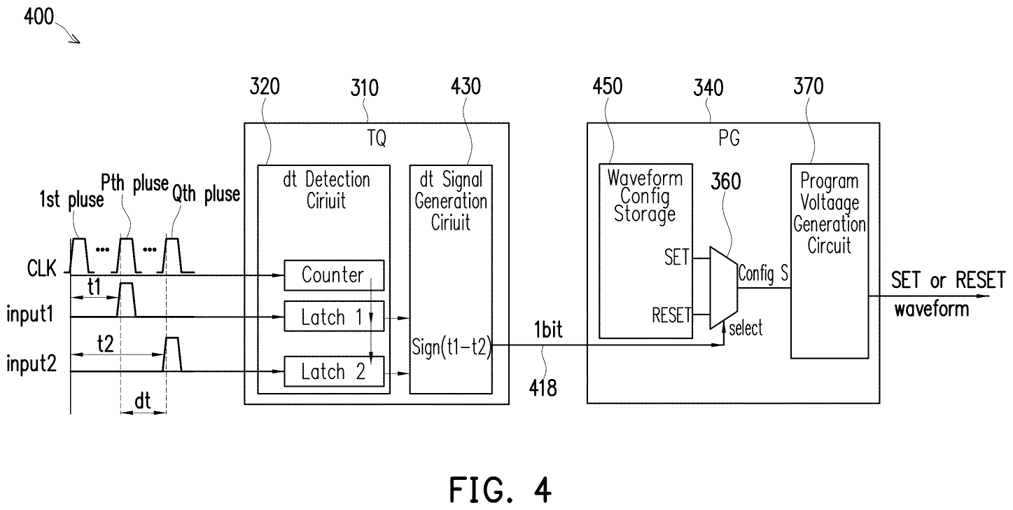

The time difference signal generation circuit 330 is coupled to the time difference detection circuit 320 to receive the first signal 325 and second signal 326 containing the corresponding counted values Q and P. The time difference signal generation circuit 330 comprises the output 313 of the time difference converter circuit and is configured to generate the time difference signal 318 based on the first signal 325 and the second signal 326. For example, the time difference signal generation circuit 330 comprises one or more logic circuits coupled to perform a subtraction operation between Q and P, and output at least one of a sign Sign(t1−t2) or a value of the time difference dt in the time difference signal 318. In the example in FIG. 3, Sign(t1−t2) of the time difference dt is positive because the first pulse input1 with the arrival rime t1 arrives after the pulse input2 with the arrival rime t2. An example where Sign(t1−t2) of the time difference dt is negative is illustrated in FIG. 4. The value of the time difference dt is the absolute value of the difference between Q and P, i.e., |Q−P|. The described configuration of the time difference converter circuit 310 is an example. Other circuits for detecting and outputting a time difference between two pulses are within the scopes of various embodiments.

The pulse generator circuit 340 comprises an input 341 coupled to the output 313 of the time difference converter circuit 310 to receive the time difference signal 318, and an output 342 at which the pulse generator circuit 340 is configured to output a program voltage Vp corresponding to the time difference signal 318. The output 342 of the pulse generator circuit 340 is configured to be coupled to the synapse device coupled between the spiking pre-synaptic neuron device and post-synaptic neuron device that generated the first pulse input1 and pulse input2, to program a weight value in the synapse device with the program voltage Vp, as described herein.

In the example configuration in FIG. 3, the pulse generator circuit 340 comprises a waveform configuration storage circuit 350, a waveform configuration selector circuit 360, and a program voltage generation circuit 370. The waveform configuration storage circuit 350 is configured to store a plurality of different waveform configurations Config 1, Config 2, to Config K, where K is a positive integer, for the program voltage Vp. The different waveform configurations Config 1, Config 2, to Config K are correspondingly associated with different signs or values of the time difference dt. In some embodiments, the waveform configuration storage circuit 350 comprises a lookup table containing the different waveform configurations Config 1, Config 2, to Config K and the correspondingly associated different signs or values of the time difference dt. In at least one embodiment, the waveform configuration storage circuit 350 comprises one or more circuit elements configured for data storage, such as register, memory, or the like.

The waveform configuration selector circuit 360 comprises the input 341 of the pulse generator circuit 340, and is coupled to the waveform configuration storage circuit 350. The waveform configuration selector circuit 360 is configured to select, among the plurality of different waveform configurations Config 1, Config 2, to Config K, a waveform configuration corresponding to at least one of a sign or a value of the time difference dt included in the time difference signal 318. For example, when the time difference signal 318 includes a positive Sign(t1−t2) and a specific value of the time difference dt, the waveform configuration selector circuit 360 is configured to select from among different waveform configurations Config 1, Config 2, to Config K, a waveform configuration Config S (where S is a positive integer between 1 and K) that is stored in the waveform configuration storage circuit 350 in association with the positive Sign(t1−t2) and the specific value of the time difference dt. The waveform configuration selector circuit 360 is configured to output the selected waveform configuration Config S in a signal 362 to the program voltage generation circuit 370. In the example configuration in FIG. 3, the waveform configuration selector circuit 360 comprises a multiplexer and the input 341 corresponds to a select input of the multiplexer. The described configuration of the waveform configuration storage circuit 350 and waveform configuration selector circuit 360 is an example. Other circuits for storing and/or selecting waveform configurations are within the scopes of various embodiments. In some embodiments, instead of storing various waveform configurations and then selecting a waveform configuration from among the stored waveform configurations, the pulse generator circuit 340 is configured to generate a required waveform based on the sign and/or value of the time difference dt included in the time difference signal 318.

The program voltage generation circuit 370 is coupled to the waveform configuration selector circuit 360 to receive the waveform configuration Config S, and is configured to generate the program voltage Vp based on the selected waveform configuration Config S. In some embodiments, the program voltage generation circuit 370 comprises a driver circuit configured to output the program voltage Vp with sufficient voltage and/or power to drive a corresponding conductive line and to program one or more memory cells coupled thereto. In at least one embodiment, signals output by one or more or all of the time difference detection circuit 320, time difference signal generation circuit 330, waveform configuration storage circuit 350, waveform configuration selector circuit 360 are digital signals which are for data processing but being insufficient in voltage or power to directly drive a conductive line and/or to program a memory cell. The program voltage generation circuit 370, in one or more embodiments, is a larger and/or more powerful circuit than the other described circuits of the programing circuit 300 and is configured so that the program voltage generation circuit 370 is capable of driving a conductive line and/or programing a memory cell with the program voltage Vp. In some embodiments, the program voltage generation circuit 370 has a configuration similar to that of a word line driver or bit line driver. In at least one embodiment, the program voltage generation circuit 370 comprises a voltage source or a current source. In at least one embodiment, the program voltage Vp is an analog voltage. Responsive to different waveform configurations output by the waveform configuration selector circuit 360, the program voltage generation circuit 370 is configured to generate program voltages Vp with different waveforms corresponding to the detected sign and/or value of the time difference dt.

In some embodiments, when the memory cell to be programmed is a PCM cell, there are two ways for programing the PCM cell, i.e., by a SET program voltage or by a RESET program voltage. A PCM cell comprises an active material arranged between two electrodes. For example, the active material comprises Ge₂Sb₂Te₅ (GST), and the two electrodes correspond to the terminals 241, 242 described herein. The active material is a phase change material which has a crystalline phase, an amorphous phase, and one or more intermediate phases in between. The PCM cell has the highest resistance (lowest conductance) in the amorphous phase, the lowest resistance (highest conductance) in the crystalline phase, and one or more intermediate resistances (or conductances) in the corresponding one or more intermediate phases. The different resistances (or conductances) of the PCM cell correspond to different data or weight values stored by the PCM cell. In an example, the PCM cell has a state 11, state 10, state 01 and state 00. The state 11 corresponds to the amorphous phase with the highest resistance (lowest conductance), the state 10 corresponds to an intermediate phase with a lower resistance (higher conductance) than state 11, the state 01 corresponds to another intermediate phase with a lower resistance (higher conductance) than state 10, and the state 00 corresponds to the crystalline phase with the lowest resistance (highest conductance). To switch the PCM cell to a state with a higher resistance (lower conductance), a RESET program voltage is applied across the active material, whereas to switch the PCM cell to a state with a lower resistance (higher conductance), a SET program voltage is applied across the active material.

A RESET program voltage has a maximum voltage value (peak voltage value) higher than a predetermined melting voltage at which the active material is melt, increasing a volume of amorphous active material, i.e., increasing resistance (lowering conductance). At a higher maximum voltage value of the RESET program voltage, the PCM cell is switched stronger toward the state 11 with the highest resistance (lowest conductance). In some embodiments, when the Sign(t1−t2) is positive, indicating that the first pulse input1 generated by a spiking pre-synaptic neuron device arrives after the pulse input2 generated by spiking post-synaptic neuron device, a waveform configuration corresponding to a RESET program voltage is selected by the waveform configuration selector circuit 360 from the waveform configuration storage circuit 350 and a corresponding RESET program voltage is generated by the program voltage generation circuit 370, to reduce the conductance of the PCM cell being programed. The maximum voltage value of the RESET program voltage depends on the value of the time difference dt. For example, at a lower value of the time difference dt, a waveform configuration corresponding to a lower maximum voltage value of the RESET program voltage is selected, and at a higher value of the time difference dt, a waveform configuration corresponding to a higher maximum voltage value of the RESET program voltage is selected. In some embodiments, waveform configurations corresponding to RESET program voltages and stored in the waveform configuration storage circuit 350 differ from each other in maximum voltage values.

A SET program voltage has a maximum voltage value (peak voltage value) lower than the predetermined melting voltage at which the active material is melt. In other words, a SET program voltage or a SET program operation is applied during a quenching time of the PCM cell when the active material cools down and crystalizes. The quenching time corresponds to the falling time of the SET program voltage from its maximum voltage value to a lowest voltage level, e.g., zero. The longer the quenching time (falling time), the stronger the PCM cell is switched toward the state 00 with the lowest resistance (highest conductance). In some embodiments, when the Sign(t1−t2) is negative, indicating that the first pulse input1 generated by a spiking pre-synaptic neuron device arrives before the pulse input2 generated by spiking post-synaptic neuron device, a waveform configuration corresponding to a SET program voltage is selected by the waveform configuration selector circuit 360 from the waveform configuration storage circuit 350 and a corresponding SET program voltage is generated by the program voltage generation circuit 370, to increase the conductance of the PCM cell being programed. The falling time of the SET program voltage depends on the value of the time difference dt. For example, at a lower value of the time difference dt, a waveform configuration corresponding to a shorter falling time of the SET program voltage is selected, and at a higher value of the time difference dt, a waveform configuration corresponding to a longer falling time of the SET program voltage is selected. In some embodiments, waveform configurations corresponding to SET program voltages and stored in the waveform configuration storage circuit 350 have about the same maximum voltage value, but differ from each other in the falling times or inclinations at the falling edges.

The described SET program voltages, RESET program voltages, and various states of PCM are examples. Other configurations are within the scopes of various embodiments. For example, in one or more embodiments, the time difference converter circuit 310 is configured to output the time difference signal 318 not as a digital signal but as an analog signal. In at least one embodiment, one or more advantages described herein are achievable by the programing circuit 300 and/or by an IC comprising the programing circuit 300.

FIG. 4 is a schematic diagram of a programing circuit 400, in accordance with some embodiments. Components of the programing circuit 400 having corresponding components in the programing circuit 300 are designated by the same reference numerals, or by the reference numerals of the programing circuit 300 increased by one hundred.

In the programing circuit 400, a time difference signal generation circuit 430 is configured to determine Sign(t1−t2) of the time difference dt and output the determined sign of the time difference dt in a time difference signal 418 to the waveform configuration selector circuit 360. The time difference signal 418 is a 1—bit signal which is at a logic high level (“1”) when Sign(t1−t2) is negative, and at a logic low level (“0”) when Sign(t1−t2) is positive. A waveform configuration storage circuit 450 stores two waveform configurations, namely, a SET waveform configuration corresponding to a SET program voltage for increasing the conductance of the PCM cell to be programmed when the time difference signal 418 is at the logic high level (“1”), and a RESET waveform configuration corresponding to a RESET program voltage for decreasing the conductance of the PCM cell to be programmed when the time difference signal 418 is at the logic low level (“0”). Based on the waveform configuration selected by the waveform configuration selector circuit 360, the program voltage generation circuit 370 is configured to generate the corresponding SET or RESET program voltage (i.e., SET or RESET waveform). In other words, when Q>P, i.e., when first pulse input1 is lagging compared to pulse input2, Sign(t1−t2) is positive, the time difference signal 418 is at logic low level (“0”), and a RESET program voltage is generated by the programing circuit 400. When Q<P, i.e., when first pulse input1 is leading compared to pulse input2, Sign(t1−t2) is negative, the time difference signal 418 is at logic high level (“1”), and a SET program voltage is generated by the programing circuit 400. The described 1-bit configuration is an example. Other configurations are within the scopes of various embodiments. In at least one embodiment, one or more advantages described herein are achievable by the programing circuit 400 and/or by an IC comprising the programing circuit 400.

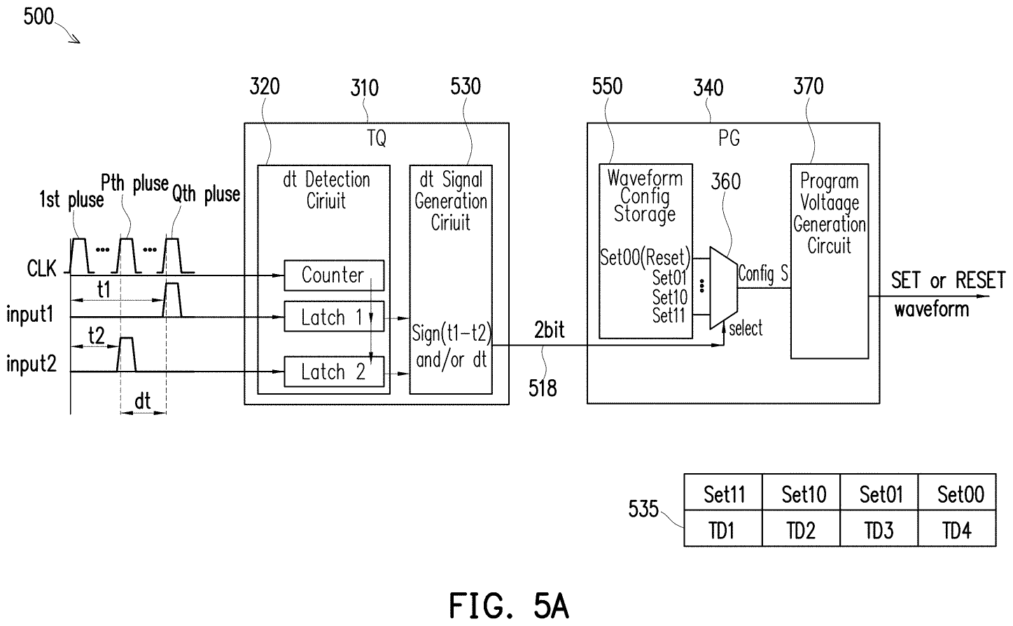

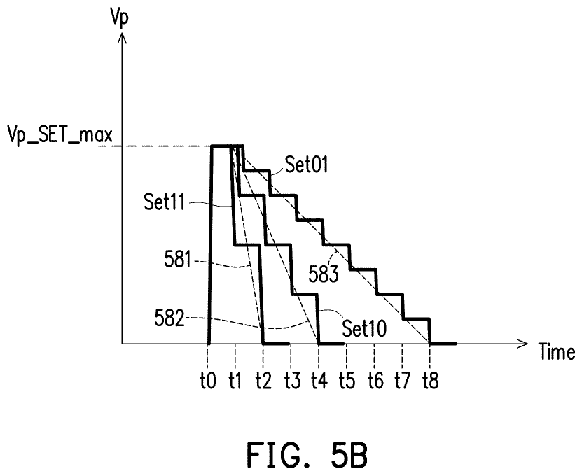

FIG. 5A is a schematic diagram of a programing circuit 500, in accordance with some embodiments. Components of the programing circuit 500 having corresponding components in the programing circuit 300 are designated by the same reference numerals, or by the reference numerals of the programing circuit 300 increased by two hundred.

In the programing circuit 500, a time difference signal generation circuit 530 is configured to output a time difference signal 518 as a 2-bit signal. Table 535 in FIG. 5A shows example 2-bit codes potentially included in the time difference signal 518. Specifically, code Set11 corresponds to bits “11”, code Set10 corresponds to bits “10”, code Set01 corresponds to bits “01”, and code Set00 corresponds to bits “00” in the time difference signal 518. Codes Sett11, Sett10, Sett01 all correspond to situations when first pulse input1 is leading compared to pulse input2, i.e., when Sign(t1−t2) is negative. Code Set11 corresponds to the value of the time difference dt being in a low range TD1 (e.g., 0-1 clock pulse), i.e., when first pulse input1 is leading pulse input2 by TD1. Code Set10 corresponds to the value of the time difference dt being in a higher range TD2 (e.g., 2-3 clock pulses). Code Set01 corresponds to the value of the time difference dt being in a further higher range TD3 (e.g., 4-5 clock pulses). Code Set00 corresponds to the value of the time difference dt being in a high range TD4 (e.g., 6-7 clock pulses). In some embodiments, when first pulse input1 is lagging compared to pulse input2, i.e., when Sign(t1−t2) is positive, and/or when the value of the time difference dt is greater than the range TD4, the time difference signal generation circuit 530 is also configured to output code Sett00 as the time difference signal 518. A waveform configuration storage circuit 550 stores four waveform configurations associated with the four possible codes included in the time difference signal 518. The waveform configurations associated with codes Set11, Set10, Set01 correspond to SET program voltages having different durations or inclinations as described, for example, with respect to FIG. 5B. The waveform configuration associated with code Set00 corresponds to a RESET program voltage. The waveform configuration selector circuit 360 is configured to, in response to the value of the time difference dt included in the time difference signal 518 in the form of a 2-bit code matching one of the codes Sett11, Sett10, Sett01, Set00, output the waveform configuration associated with the matched code. Based on the waveform configuration selected by the waveform configuration selector circuit 360, the program voltage generation circuit 370 is configured to generate the corresponding SET or RESET program voltage (i.e., SET or RESET waveform).

FIG. 5B is a timing diagram showing example program voltages generated by the programing circuit 500, in accordance with some embodiments. The example program voltages in FIG. 5B correspond to the SET program voltages associated with codes Set11, Set10, Set01 in the time difference signal 518, and are designated by the associated codes. The SET program voltages Set1, Set10, Set01 have the same maximum voltage value Vp_SET_max which, as described herein, is lower than the melting voltage of an active material in the PCM cell to be programmed. The SET program voltages Set11, Set10, Set01 have different durations or inclinations. For example, the duration of the SET program voltage Set11 is 2 cycles from t0 to t2, the duration of the SET program voltages Set10 is 4 cycles from t0 to t4, and the duration of the SET program voltages Set01 is 8 cycles from t0 to t8. The falling time or quenching time of the SET program voltage Set11 is one cycle, as it takes the SET program voltage Set11 one cycle between t1 and t2 to fall from Vp_SET_max to zero. The inclination (or slope) 581 of the SET program voltage Set11 is the steepest among the inclinations 581, 582, 583 of the SET program voltages Set11, Set10, Set01. The falling time or quenching time of the SET program voltage Set10 is three cycles, as it takes the SET program voltage Set10 three cycles between t1 and t4 to fall from Vp_SET_max to zero. The inclination 582 of the SET program voltage Set10 is the second steepest. The falling time or quenching time of the SET program voltage Set01 is seventh cycles, as it takes the SET program voltage Set01 seven cycles between t1 and t8 to fall from Vp_SET_max to zero. The inclination 583 of the SET program voltage Set01 is the least steep.

Thus, when the first pulse input1 is slightly leading pulse input2, i.e., the value of the time difference dt is low (e.g., corresponding to code Set11), the programing circuit 500 is configured to generate a corresponding SET program voltage (e.g., program voltage Set11 in FIG. 5B) with a short falling time to slightly increase the conductance of the PCM cell being programed. When the first pulse input1 is leading pulse input2 further, i.e., the value of the time difference dt is higher (e.g., corresponding to code Set10), the programing circuit 500 is configured to generate a corresponding SET program voltage (e.g., program voltage Set10 in FIG. 5B) with a longer falling time to increase the conductance of the PCM cell by a greater amount. When the first pulse input1 is leading pulse input2 even further, i.e., the value of the time difference dt is even higher (e.g., corresponding to code Set01), the programing circuit 500 is configured to generate a corresponding SET program voltage (e.g., program voltage Set01 in FIG. 5B) with an even longer falling time to increase the conductance of the PCM cell by an even greater amount. This arrangement advantageously matches the STDP rule, in one or more embodiments.

The described 2-bit configuration is an example. Other configurations are within the scopes of various embodiments. For example, in at least one embodiment, the RESET program voltage is associated with one of the codes Set11 Set10, Set01, whereas the code Set00 is associated with a SET program voltage. For another example, it is possible to arrange codes Set11-Set00 in orders different from the order based on the value of the time difference as described herein. Such re-arrangements will lead to different relationships between the value of the time difference and the falling time of the SET program voltages. In at least one embodiment, one or more advantages described herein are achievable by the programing circuit 500 and/or by an IC comprising the programing circuit 500.

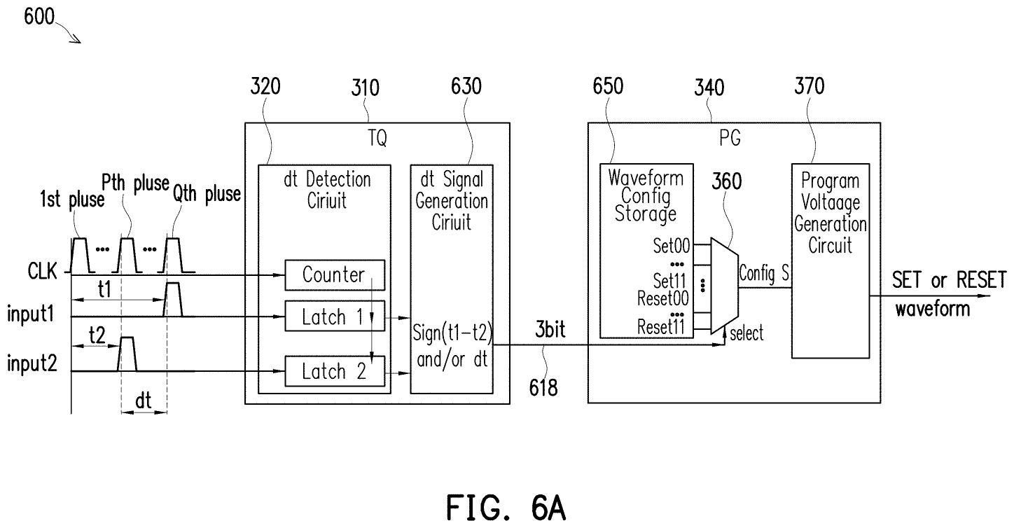

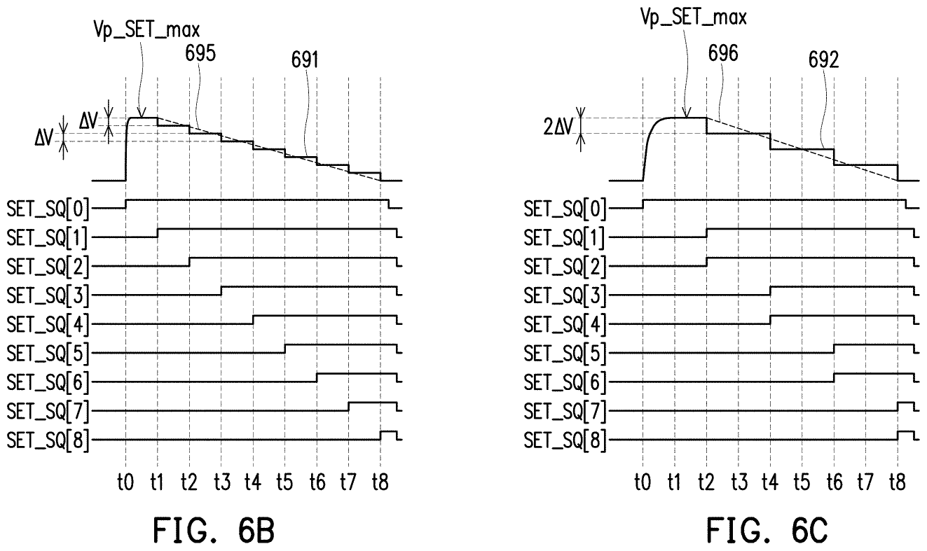

FIG. 6A is a schematic diagram of a programing circuit 600, in accordance with some embodiments. Components of the programing circuit 600 having corresponding components in the programing circuit 300 are designated by the same reference numerals, or by the reference numerals of the programing circuit 300 increased by three hundred.

In the programing circuit 600, a time difference signal generation circuit 630 is configured to output a time difference signal 618 as a 3-bit signal. In some embodiments, one bit, e.g., the first bit, of the 3-bit signal 618 indicates the sign of the time difference dt, i.e., Sign(t1−t2). In at least one embodiment, the first bit of the 3-bit signal 618 is assigned a logic level in the same manner as the time difference signal 418, i.e., the first bit of the 3-bit signal 618 is at a logic high level (“1”) when Sign(t1−t2) is negative, and at a logic low level (“0”) when Sign(t1−t2) is positive. The other two bits of the 3-bit signal 618 form four codes correspondingly associated with four different waveform configurations. As a result, the 3-bit signal 618 provides eight different codes, including four codes associated with four different SET program voltages when the first pulse input1 is leading, i.e., Sign(t1−t2) is negative, and four different RESET program voltages when the first pulse input1 is lagging, i.e., Sign(t1−t2) is positive. In a waveform configuration storage circuit 650, four waveform configurations for the four different SET program voltages are stored as codes Set00, Set01, Set10, Set11, and four waveform configurations for the four different RESET program voltages are stored as codes Reset00, Reset01, Reset10, Reset11. Based on the waveform configuration selected by the waveform configuration selector circuit 360, the program voltage generation circuit 370 is configured to generate the corresponding SET or RESET program voltage (i.e., SET or RESET waveform).

In at least one embodiment, the four different SET program voltages have the same peak voltage value, but with different durations or different falling/quenching times corresponding to the value of the time difference dt falling in different ranges TD1-TD4, as described with respect to FIG. 5B. In one or more embodiments, the SET program voltage with the shortest quenching time comprises a single pulse, i.e., the shortest quenching time is zero. In some embodiments, for values of the time difference dt higher than the highest range TD4, the code Set00 is output by the time difference signal generation circuit 630, and the corresponding SET program voltage Set00 with the longest quenching time is selected and output by the pulse generator circuit 340

In at least one embodiment, the four different RESET program voltages each have a single pulse, but with different peak voltage values corresponding to different values of the time difference dt. For example, the RESET program voltage associated with the code Reseal has the highest peak voltage value corresponding to the value of time difference dt in a high range, e.g., the range TD4 described with respect to FIG. 5A, the RESET program voltage associated with the code Reset10 has a lower peak voltage value corresponding to the value of time difference dt in a next range, e.g., the range TD3, the RESET program voltage associated with the code Reset01 has an even lower peak voltage value corresponding to the value of time difference dt in a further range, e.g., the range TD2, and the RESET program voltage associated with the code Reset00 has the lowest peak voltage value corresponding to the value of time difference dt in the lowest range, e.g., the range TD1. In at least one embodiment, the lowest peak voltage value corresponding to the code Reset00 is zero, i.e., there is no program voltage is to be output by the pulse generator circuit 340. In some embodiments, for values of the time difference dt higher than the highest range TD4, the code Reset11 is output by the time difference signal generation circuit 630, and the corresponding RESET program voltage Reset11 with the highest peak voltage value is selected and output by the pulse generator circuit 340.

FIGS. 6B and 6C are timing diagram showing corresponding example program voltages 691, 692 generated by the programing circuit 600, in accordance with some embodiments. The program voltages 691, 692 are SET program voltages. In at least one embodiment, the SET program voltage 691 in FIG. 6B corresponds to the code Set00 with the longest quenching time.

FIG. 6B further includes timing diagrams of bits SET_SQ(0) to SET_SQ(8) in a 9-bit code SET_SQ that defines the waveform configuration of the SET program voltage 691. The 9-bit code SET_SQ is stored in the waveform configuration storage circuit 650 as a waveform configuration associated with a specific combination of Sign(t1−t2) and the value of time difference dt, as described herein. In one or more embodiments, other waveform configurations in the waveform configuration storage circuits 650, 550, 450, 350 are stored in similar code formats, and the program voltage generation circuit 370 is configured to generate program voltages based on the codes of the stored waveform configurations in a manner similar to that described herein below with respect to the SET program voltage 691.

In response to bit SET_SQ(0) switched from “0” to “1,” the program voltage generation circuit 370 is configured to raise a voltage level of the program voltage being generated, e.g., the SET program voltage 691, from zero to a predetermined voltage level Vp_SET_max. Subsequently, every time one of remaining bits SET_SQ(1) to SET_SQ(8) is switched from “0” to “1,” the program voltage generation circuit 370 is configured to reduce the voltage level of the SET program voltage 691 by a predetermined amount ΔV. If none of bits SET_SQ(1) to SET_SQ(8) are switched, the program voltage generation circuit 370 is configured to maintain the current voltage level of the SET program voltage 691. For example, at time t1, in response to bit SET_SQ(1) switched from “0” to “1,” the program voltage generation circuit 370 is configured to reduce the voltage level of the SET program voltage 691, currently at Vp_SET_max, by ΔV. At time t2, in response to bit SET_SQ(2) switched from “0” to “1,” the program voltage generation circuit 370 is configured to further reduce the voltage level of the SET program voltage 691 by another amount of ΔV, and so on. As a result, the program voltage generation circuit 370 is configured to generate the SET program voltage 691 to have a stepwise waveform configuration in which the voltage level of the SET program voltage 691 is reduced by a step ΔV, at each of times t1-t8, from Vp_SET_max at time t1 to zero at time t8, at an inclination 695.

FIG. 6C also includes timing diagrams of bits SET_SQ(0) to SET_SQ(8) in another 9-bit code SET_SQ that defines the waveform configuration of the SET program voltage 692. The code SET_SQ for the SET program voltage 692 is different from the code SET_SQ for the SET program voltage 691 in the timing when one or more of bits SET_SQ(1) to SET_SQ(8) is/are switched. For example, at time t1, bit SET_SQ(1) in the code for SET program voltage 691 is switched as described with respect to FIG. 6B; however, the same bit SET_SQ(1) at the same time t1 in the code for SET program voltage 692 in FIG. 6C is not switched. As a result, the voltage level of SET program voltage 692 at time t1 remains at Vp_SET_max. At time t2, in response to each of two bits SET_SQ(1) and SET_SQ(2) switched from “0” to “1,” the program voltage generation circuit 370 is configured to reduce the voltage level of the SET program voltage 692 by ΔV. Because there are two bits being switched, two amounts of ΔV are reduced from the voltage level of SET program voltage 692, resulting in a larger reduction step of 2ΔV as indicated in FIG. 6C. As a result, the program voltage generation circuit 370 is configured to generate the SET program voltage 692 to have a stepwise waveform configuration in which the voltage level of the SET program voltage 692 is reduced by the larger step of 2ΔV, at each of times t2, t4, t6, t8, from Vp_SET_max at time t2 to zero at time t8, at an inclination 696 which is slightly steeper than the inclination 695 of SET program voltage 691. The quenching time of the SET program voltage 692 is six cycles (from t2 to t8), i.e., shorter than the quenching time of the SET program voltage 691 at seven cycles (from t1 to t8). Both SET program voltages 691, 692 increase the conductance of the PCM cell being programmed, but the conductance increase cause by the SET program voltage 692 is less than the conductance increase cause by the SET program voltage 691.

The described arrangement for storing waveform configurations and using the stored waveform configurations to generate corresponding program voltages is an example. Other configurations are within the scopes of various embodiments. For example, to cause the program voltage generation circuit 370 to generate the SET program voltage Set10 in FIG. 5B, the corresponding stored code SET_SQ has bits SET_SQ(1) and SET_SQ(2) switched at t1, bits SET_SQ(3) and SET_SQ(4) switched at t2, SET_SQ(5) and SET_SQ(6) switched at t3, and bits SET_SQ(7) and SET_SQ(7) switched at t4. For another example, to cause the program voltage generation circuit 370 to generate the SET program voltage Set11 in FIG. 5B, the corresponding stored code SET_SQ has four bits from SET_SQ(1) to SET_SQ(4) switched at t1, and four remaining bits from SET_SQ(5) to SET_SQ(8) switched at t2. In some embodiments, the program voltage generation circuit 370 is configured to reduce the voltage level of the program voltage being generated in response to a bit of code SET_SQ switched from “1” to “0.” In at least one embodiment, by varying the timing when one or more bits in the stored code SET_SQ is switched, it is possible to cause the program voltage generation circuit 370 to generate program voltages of different waveform configurations, with further effects on how the PCM cell is programed. In at least one embodiment, one or more advantages described herein are achievable by the programing circuit 600 and/or by an IC comprising the programing circuit 600.

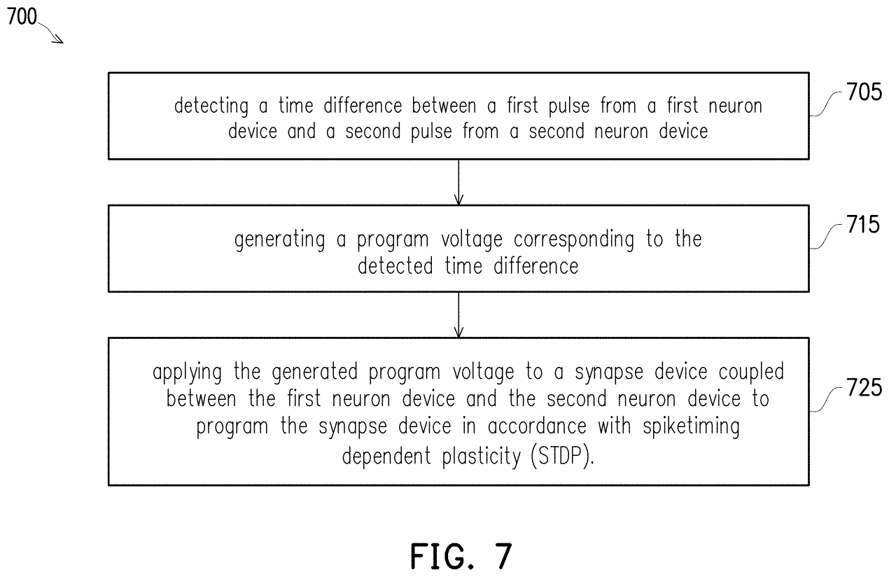

FIG. 7 is a flowchart of a method 700 in accordance with some embodiments. In at least one embodiment, the method 700 is performed in or by one or more neural networks, ICs, or programming circuits described with respect to FIGS. 1A-6C.

At operation 705, a time difference between a first pulse from a first neuron device and a second pulse from a second neuron device is detected. For example, as discussed with respect to FIG. 1B, a time difference between a first pulse IN1 from a first neuron device A₁ and a second pulse IN2 from a second neuron device B₂ is detected. For a further example, as discussed with respect to one or more of FIGS. 2A-2B, a time difference between a first pulse IN1_1 from a first neuron device and a second pulse IN2_1 from a second neuron device is detected. For yet another example, as discussed with respect to one or more of FIGS. 3, 4, 5A, 6A, a time difference dt between a first pulse input1 from a first neuron device and a second pulse input2 from a second neuron device is detected. In at least one embodiment, the time difference is detected by a time difference converter circuit or a time difference detection circuit 320, as described with respect to FIGS. 2A and 3.

At operation 715, a program voltage corresponding to the detected time difference is generated. For example, as described with respect to FIGS. 2A-6C, a program voltage Vp is generated by a pulse generator circuit 217 or a program voltage generation circuit 370, as described with respect to FIGS. 2A and 3. In some embodiments, as described with respect to FIGS. 3-6C, information of the detected time difference dt is sent in a time difference signal 318, 418, 518, 618 to a waveform configuration selector circuit 360. The information represents at least one of a sign or a value of the detected time difference. A waveform configuration storage circuit 350, 450, 550, 650 stores a plurality of different waveform configurations each correspondingly associated with at least one of a different sign or a different value of the time difference. The waveform configuration selector circuit 360 selects, from among the plurality of stored different waveform configurations, the waveform configuration associated with the sign and/or value of the detected time difference, as indicated by the information included in the time difference signal. The program voltage Vp is generated by the program voltage generation circuit 370 based on the selected waveform configuration. In some embodiments, in response to different signs and/or values of the time difference, different program voltages are correspondingly generated. The program voltages differ from each other in at least one of program voltage type (e.g., SET or RESET program voltage), duration, maximum voltage value, falling time from the maximum voltage value to a predetermined voltage value (e.g., zero), inclination of the waveform in the falling time, or the like.

In at least one embodiment, the information of the time difference included in the time difference signal is represented by a code of 1 bit, 2 bits or 3 bits, as described with respect to FIGS. 3-6C. In some embodiments, the time difference signal is an analog signal, rather than a digital signal. In one or more embodiments, the waveform configurations are stored in the form of multi-bit codes, as described with respect to FIGS. 6B-6C. Other code formats and/or other arrangement for presenting the information about the time difference and/or the stored waveform configurations are within the scopes of various embodiments.

At operation 725, the generated program voltage is applied to a synapse device coupled between the first neuron device and the second neuron device to program the synapse device in accordance with spike-timing dependent plasticity (STDP). For example, as discussed with respect to FIG. 1B, a synapse device corresponding to the connection W12 between node A₁ and node B₂ is programmed by the generated program voltage in accordance with the STDP rule. For another example, as described with respect to FIGS. 2A-2B, a memory cell MC or MC′ corresponding to a synapse device between the spiking pre-synaptic neuron device and post-synaptic neuron device is programed by the generated program voltage in accordance with the STDP rule, e.g., to increase conductance of (i.e., set) the memory cell when the first pulse from the spiking pre-synaptic neuron device is leading (arrives before) the second pulse from the spiking post-synaptic neuron device, and to decrease the conductance of (i.e., reset) the memory cell when the first pulse is lagging behind (arrives after) the second pulse. In some embodiments, the memory cell to be programed is a PCM cell, and SET program voltages with different quenching times are correspondingly generated for different values of the time difference. In at least one embodiment, one or more advantages described herein are achievable in the method 700.

The described methods and algorithms include example operations, but they are not necessarily required to be performed in the order shown. Operations may be added, replaced, changed order, and/or eliminated as appropriate, in accordance with the spirit and scope of embodiments of the disclosure. Embodiments that combine different features and/or different embodiments are within the scope of the disclosure and will be apparent to those of ordinary skill in the art after reviewing this disclosure.

In some embodiments, a programming circuit for a neural network comprises a time difference converter circuit and a pulse generator circuit. The time difference converter circuit comprises a first input configured to receive a first pulse from a first neuron device in the neural network, a second input configured to receive a second pulse from a second neuron device in the neural network, and an output at which the time difference converter circuit is configured to output a time difference signal corresponding to a time difference between the first pulse and the second pulse. The neural network further comprises a synapse device coupled between the first neuron device and the second neuron device. The pulse generator circuit comprises an input coupled to the output of the time difference converter circuit to receive the time difference signal, and an output at which the pulse generator circuit is configured to output a program voltage corresponding to the time difference signal. The output of the pulse generator circuit is configured to be coupled to the synapse device to program a weight value in the synapse device with the program voltage.

In some embodiments, an integrated circuit comprises a plurality of first conductive lines, a plurality of second conductive lines, an array of memory cells each coupled to a corresponding first conductive line among the plurality of first conductive lines and a corresponding second conductive line among the plurality of second conductive lines, and a plurality of programming circuits correspondingly coupled to the plurality of first conductive lines. Each of the plurality of programming circuits is configured to detect a time difference between a first pulse and a second pulse, generate a program voltage corresponding to the detected time difference, and output the generated program voltage to the corresponding first conductive line to program a corresponding memory cell in the array of memory cells with the program voltage.

In some embodiments, a method comprises detecting a time difference between a first pulse from a first neuron device and a second pulse from a second neuron device, generating a program voltage corresponding to the detected time difference, and applying the generated program voltage to a synapse device coupled between the first neuron device and the second neuron device to program the synapse device in accordance with spike-timing dependent plasticity (STDP).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A programming circuit for a neural network, the programming circuit comprising:
a time difference converter circuit comprising:
a first input configured to receive a first pulse from a first neuron device in the neural network,
a second input configured to receive a second pulse from a second neuron device in the neural network, the neural network further comprising a synapse device coupled between the first neuron device and the second neuron device, and
an output at which the time difference converter circuit is configured to output a time difference signal corresponding to a time difference between the first pulse and the second pulse; and
a pulse generator circuit comprising:
an input coupled to the output of the time difference converter circuit to receive the time difference signal, and
an output at which the pulse generator circuit is configured to output a program voltage corresponding to the time difference signal, wherein the output of the pulse generator circuit is configured to be coupled to the synapse device to program a weight value in the synapse device with the program voltage.

2. The programming circuit of claim 1, wherein
the time difference converter circuit is configured to generate the time difference signal including a sign of the time difference, and
the pulse generator circuit is configured to
in response to the sign of the time difference included in the time difference signal being positive, generate the program voltage as one of a SET program voltage to set the synapse device and a RESET program voltage to reset the synapse device, and
in response to the sign of the time difference included in the time difference signal being negative, generate the program voltage as the other of the SET program voltage and the RESET program voltage.

3. The programming circuit of claim 1, wherein
the time difference converter circuit is configured to generate the time difference signal including a value of the time difference, and
the pulse generator circuit is configured to, in response to the value of the time difference included in the time difference signal matching one of a plurality of different time difference values, generate the program voltage as a corresponding one of a plurality of different program voltages.

4. The programming circuit of claim 3, wherein
the plurality of different program voltages has corresponding different waveforms, and
the different waveforms differ from each other in at least one of duration, inclination, or maximum voltage value.

5. The programming circuit of claim 1, wherein
the time difference converter circuit comprises:
a time difference detection circuit configured to detect the time difference between the first pulse and the second pulse, and
a time difference signal generation circuit coupled to the time difference detection circuit, and configured to generate the time difference signal based on the detected time difference.

6. The programming circuit of claim 5, wherein
the time difference detection circuit comprises:
a first latch comprising the first input of the time difference converter circuit, and configured to generate a first signal corresponding to the first pulse and based on a clock signal, and
a second latch comprising the second input of the time difference converter circuit, and configured to generate a second signal corresponding to the second pulse and based on the clock signal, and
the time difference signal generation circuit is coupled to the first latch and the second latch to receive the first signal and the second signal, the time difference signal generation circuit comprising the output of the time difference converter circuit and configured to generate the time difference signal based on the first signal and the second signal.

7. The programming circuit of claim 6, wherein
the time difference detection circuit further comprises a counter configured to generate a count value signal based on the clock signal, and output the count value signal to the first latch and the second latch,
the first latch is configured to, in response to the first pulse, latch a first value of the count value signal, and output the first value in the first signal to the time difference signal generation circuit, and
the second latch is configured to, in response to the second pulse, latch a second value of the count value signal, and output the second value in the second signal to the time difference signal generation circuit.

8. The programming circuit of claim 1, wherein
the pulse generator circuit comprises:
a waveform configuration storage circuit configured to store a plurality of different waveform configurations for the program voltage, the plurality of different waveform configurations correspondingly associated with different signs or values of the time difference,
a waveform configuration selector circuit configured to select, among the plurality of different waveform configurations, a waveform configuration corresponding to at least one of a sign or a value of the time difference included in the time difference signal, and
a program voltage generation circuit configured to generate the program voltage based on the selected waveform configuration.

9. The programming circuit of claim 8, wherein at least one of
the waveform configuration storage circuit comprises a lookup table containing the plurality of different waveform configurations and the correspondingly associated different signs or values of the time difference, or
the waveform configuration selector circuit comprises a multiplexer having a select input coupled to the output of the time difference converter circuit.

10. The programming circuit of claim 8, wherein
the waveform configuration storage circuit is configured to store each of the plurality of different waveform configurations as a plurality of bits, and
the program voltage generation circuit is configured to, in response to each bit among the plurality of bits of the selected waveform configuration being switched from one of the logic high level and the logic low level to the other, reduce a voltage level of the program voltage being generated by a predetermined amount.

11. An integrated circuit, comprising:
a plurality of first conductive lines;
a plurality of second conductive lines;
an array of memory cells each coupled to
a corresponding first conductive line among the plurality of first conductive lines, and
a corresponding second conductive line among the plurality of second conductive lines; and
a plurality of programming circuits correspondingly coupled to the plurality of first conductive lines, each of the plurality of programming circuits configured to
detect a time difference between a first pulse and a second pulse,
generate a program voltage corresponding to the detected time difference, and
output the generated program voltage to the corresponding first conductive line to program a corresponding memory cell in the array of memory cells with the program voltage.

12. The integrated circuit of claim 11, wherein
each memory cell in the array of memory cells comprises a controllably variable resistor having
a first terminal coupled to the corresponding first conductive line, and
a second terminal coupled to the corresponding second conductive line.

13. The integrated circuit of claim 11, wherein
each memory cell in the array of memory cells comprises
a controllably variable resistor having a first terminal coupled to the corresponding first conductive line, and a second terminal, and
an access transistor having a gate terminal coupled to the corresponding second conductive line, and a drain or source terminal coupled to the second terminal of the controllably variable resistor.

14. The integrated circuit of claim 11, further comprising:
a plurality of first neuron devices correspondingly coupled to the plurality of first conductive lines; and
a plurality of second neuron devices correspondingly coupled to the plurality of second conductive lines,
wherein each of the memory cells in the array of memory cells comprises a synapse device coupled between
a corresponding first neuron device among the plurality of first neuron devices, and
a corresponding second neuron device among the plurality of second neuron devices.

15. The integrated circuit of claim 11, wherein
each memory cell in the array of memory cells comprises a phase change memory (PCM) cell, and
each of the plurality of programming circuits is configured to generate the program voltage for programing a corresponding memory cell in the array of memory cells as a SET program voltage during a quenching time of the corresponding memory cell.

16. A method, comprising:
detecting a time difference between a first pulse from a first neuron device and a second pulse from a second neuron device;
generating a program voltage corresponding to the detected time difference; and
applying the generated program voltage to a synapse device coupled between the first neuron device and the second neuron device to program the synapse device in accordance with spike-timing dependent plasticity (STDP).

17. The method of claim 16, wherein
the synapse device comprises a phase change memory (PCM),
the program voltage comprises a SET program voltage, and
said applying comprises applying the SET program voltage to the synapse device during a quenching time of the synapse device.

18. The method of claim 16, wherein
the program voltage is decreased in a stepwise manner from a maximum voltage value.

19. The method of claim 16, further comprising:
storing a plurality of different waveform configurations correspondingly associated with different values of the time difference; and
selecting, among the plurality of different waveform configurations, a waveform configuration corresponding to a value of the detected time difference,
wherein said generating comprises generating the program voltage based on the selected waveform configuration.

20. The method of claim 19, wherein
the plurality of different waveform configurations corresponds to different waveforms of the program voltage, and
the different waveforms have corresponding different inclinations from a maximum voltage value.
